(19) United States
(12) Patent Application Publication
(10) Pub. No.: US 2011/0070746 A1
(43) Pub. Date: Mar. 24, 2011

(54) METHOD OF INCREASING OPERATION SPEED AND SATURATED CURRENT OF SEMICONDUCTOR DEVICE AND METHOD OF REDUCING SITE FLATNESS AND ROUGHNESS OF SURFACE OF SEMICONDUCTOR WAFER

(76) Inventor: TE-YIN KAO, Taipei (TW)

(21) Appl. No.: 12/565,781

(22) Filed: Sep. 24, 2009

(51) Int. Cl. H01L 21/26

(52) U.S. Cl. 438/795; 257/E21.328

(57) ABSTRACT

A method of increasing the operation speed and the saturated current of a semiconductor device to be formed on a semiconductor wafer is described, including a step of reducing the site flatness and the roughness of the surface of the semiconductor wafer before the semiconductor device is formed. The step of reducing the site flatness and the roughness of the wafer surface includes annealing the semiconductor wafer in an atmosphere that contains at least one of H₂ and D₂ and has a pressure not more than 760 Torr.

### BACKGROUND OF THE INVENTION

1. Field of the Invention

The present invention relates to a semiconductor process. More particularly, the present invention relates to a method of reducing the site flatness and the roughness of the surface of a semiconductor wafer, and to a method of increasing the operation speed and saturated current of a semiconductor device to be formed on a semiconductor wafer, wherein the latter method is based on the former method.

2. Description of the Related Art

An uneven surface of a semiconductor wafer is usually characterized by three parameters of different scales, which include site flatness (SFQR) in the order of 10 nm, nano-topography in the order of 1 nm and roughness in the order of 0.1 nm or below. As the linewidth of semiconductor process is rapidly reduced, the requirement for the smoothness of the surface of a wafer continuously gets higher for accurate pattern transfer, lower current leakage, lower channel resistance and higher operation speed, etc. For example, the SFQR required by the International Technology Roadmap for Semiconductors (ITRS) for a wafer used in a 65 nm process is less than 0.05 μm.

In the prior art, the unevenness of the surface of a semiconductor wafer can be reduced with chemical mechanical polishing (CMP), which uses a polishing pad and a slurry containing very fine particles to polish the surface of the wafer. However, due to the limitations on the nature of the polishing pad and the size of the fine particles, it is difficult to meet the requirement for the smoothness of the surface of a semiconductor wafer with CMP.

Another method of reducing the unevenness is to form an epitaxial layer on the wafer with an epitaxial growth process. However, because the surface topology of the epitaxial layer relatively depends on that of the wafer, the reduction in the unevenness, i.e., the difference between the site flatness/nanotopography/roughness of the surface of the original wafer and that of the surface of the epitaxial layer on the wafer, is limited.

### SUMMARY OF THE INVENTION

Accordingly, this invention provides a method of reducing the site flatness and the roughness of the surface of a semiconductor wafer.

This invention also provides a method of increasing the operation speed and the saturated current of a semiconductor device to be formed on a semiconductor wafer, which is based on the above site-flatness/roughness reduction method of this invention.

The method of reducing the site flatness and the roughness of the surface of a semiconductor wafer of this invention includes annealing the semiconductor wafer in an atmosphere that contains at least one of H₂ and D₂ and has a pressure not more than 760 Torr, wherein H₂/D₂ means hydrogen/deuterium gas.

The method of increasing the operation speed and the saturated current of a semiconductor device to be formed on a semiconductor wafer of this invention includes a step of reducing the site flatness and the roughness of the surface of the wafer before the semiconductor device is formed. The step of reducing the site flatness and the roughness includes annealing the semiconductor wafer in an atmosphere that contains at least one of H₂ and D₂ and has a pressure not more than 760 Torr.

Since the site flatness and the roughness of the surface of a semiconductor wafer can be reduced by H₂/D₂-annealing under a pressure not more than 760 Torr, the operation speed and saturated current of the device can be increased effectively. Moreover, for the surface geometry improvement occurs to both of the area for forming NMOS transistors and that for forming PMOS transistors in this invention, the performance enhancement occurs to both of NMOS and PMOS transistors. On the other hand, only PMOS transistors are sped up with the Ge-strained silicon technology in the prior art.

It is further noted that most of the speed improvement is due to the roughness reduction and the carrier mobility improvement. A roughness smaller than 0.1 nm is possibly achieved with this invention, and such a small roughness is unique and can be made through H₂/D₂-annealing only, as the inventor knows.

It is to be understood that both the foregoing general description and the following detailed description are exemplary, and are intended to provide further explanation of the invention as claimed.

### BRIEF DESCRIPTION OF THE DRAWINGS

FIG. 1 shows possible timing for applying a method of increasing the operation speed and saturated current of a semiconductor device of this invention according to an embodiment of this invention.

FIG. 2 plots the variation of the surface flatness of a silicon wafer with the H₂-annealing time in an example of this invention.

FIG. 3 plots the variation of the speed of a 4T static dynamic random memory (SRAM) device with the site flatness of the wafer in the same example of this invention.

FIG. 4 plots the variation of the mean square roughness (Rₘₛ) of the silicon wafer with the H₂-annealing time in the same example of this invention.

FIG. 5 plots the variation of the speed of the 4T static dynamic random memory (SRAM) device with the Rₘₛ of the wafer surface in the same example of this invention.

FIG. 6 shows the Iₒₙ-I_{off} correlations of four groups of 4T-SRAM devices in an experiment, each group being formed on an Si-wafer that has been subjected to one of four different surface treatments including an H₂-annealing treatment of this invention.

### DESCRIPTION OF THE EMBODIMENTS

The method of increasing the operation speed and the saturated current of a semiconductor device to be formed on a semiconductor wafer of this invention includes a step of reducing the site flatness and the roughness of the surface of the semiconductor wafer before the semiconductor device is formed, which includes annealing the wafer in an atmosphere that contains at least one of H₂ and D₂ and has a pressure not more than 760 Torr The following embodiment is intended to further explain this invention but not to restrict the scope of the same.

According to the embodiments of this invention, the semiconductor wafer may include at least one material selected from the group consisting of silicon, germanium and gallium arsenide (GaAs). When the semiconductor wafer includes silicon, it is annealed preferably at 1000-1400° C. for 1-4 hours. When the semiconductor wafer includes germanium or SiGe, it is annealed preferably at 800-1400° C. for 1-4 hours. The high annealing temperature facilitates the bonding of H₂ and D₂ molecules to silicon atoms at the wafer surface as well as the rearrangement of the silicon atoms, and the annealing time is sufficient to achieve the site flatness and the roughness required by the semiconductor process to which the semiconductor wafer is applied.

In addition, it is possible that the semiconductor wafer is doped with at least one dopant selected from the group consisting of boron, gallium, phosphorous and arsenic. It is noted that a semiconductor wafer, such as a silicon wafer, is usually lightly doped as provided, and such a semiconductor wafer is typically obtained by slicing a lightly doped semiconductor ingot that is generally grown from a melt of the corresponding semiconductor material containing the corresponding dopant(s).

Moreover, it is possible to generate plasma in the atmosphere for annealing the wafer to produce more active hydrogen species that have greater capability to rearrange the silicon atoms at the wafer surface and thereby allow the annealing temperature to be lowered. In such cases, the wafer may be annealed at 400-800° C. for 1-4 hours.

In addition, the atmosphere in which the annealing is conducted has a pressure not more than 760 Torr. If the pressure exceeds 760 Torr, the effect of Si—Si atoms self-moving and self-flatting will be suppressed.

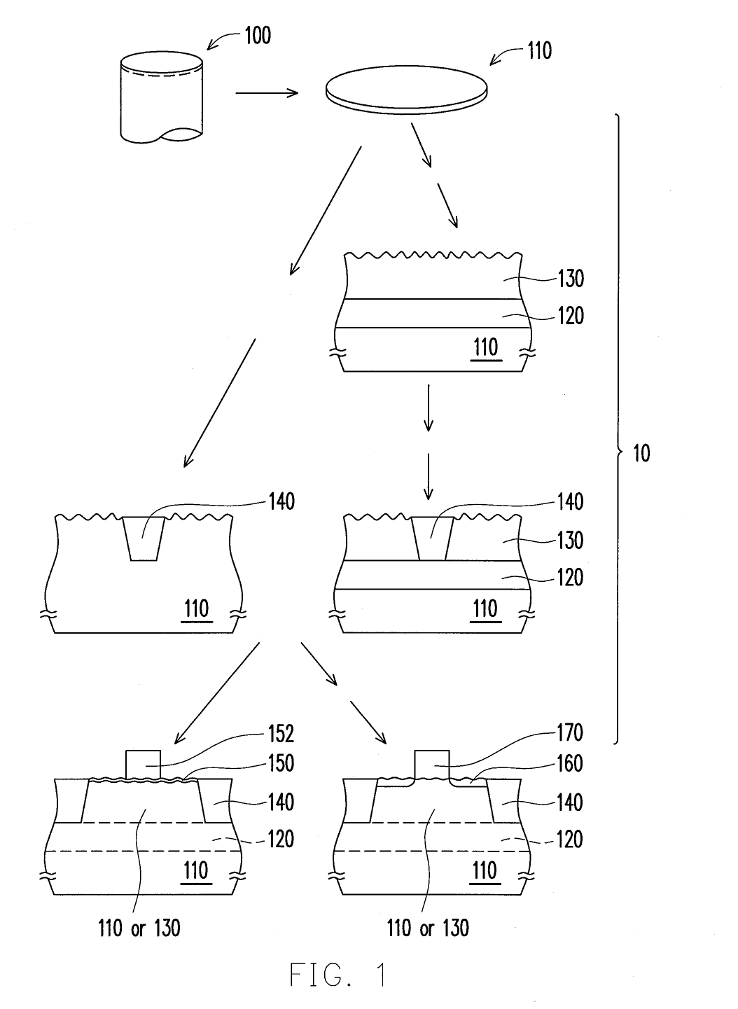

FIG. 1 shows possible timing for applying a method of increasing the operation speed and saturated current of a semiconductor device of this invention according to an embodiment of this invention. The semiconductor device exemplified here is a MOS transistor, which typically includes a gate dielectric layer, a gate electrode on the gate dielectric layer and two source/drain regions in the substrate beside the gate electrode.

The H₂/D₂-annealing can be conducted at any suitable time point(s) during the period 10 between the step of slicing a lightly-doped or undoped ingot 100 to obtain the semiconductor wafer 110 and the steps for forming the transistor. The semiconductor wafer 110 may be further processed to form semiconductor-on-insulator (SOI) wafer that includes a thin insulator 120 and a thin semiconductor film 130 thereon, wherein the thin semiconductor film 130 may be a portion of the original wafer 110 or a portion of another wafer that was previously bonded to the insulator 120 and then thinned out.

The annealing may be conducted before or after the isolation structure 140, such as a shallow trench isolation (STI) structure, is formed on the wafer 110 or in the thin semiconductor layer 130 of the SOI wafer. For example, the annealing may be done right after the wafer 110 is divided from the ingot 100, right after the semiconductor layer 130 of the SOI wafer is formed, and/or right after the isolation structure 140 is formed on the wafer 110 or in the thin semiconductor layer of the SOI wafer.

On the other hand, the annealing is conducted before the first step of the whole process for forming the MOS transistor, wherein the first step may be a step of forming a gate dielectric layer 150, or a step of forming a dummy gate 170 followed by a step of forming two S/D regions 160 with the dummy gate 170 as an implantation mask. After the gate dielectric layer 150 is formed, a gate electrode 152 can be formed on the gate dielectric layer 150. The gate electrode 152 in FIG. 1 represents the gate electrode of an NMOS transistor or that of a PMOS transistor.

Since the above surface geometry improvement occurs to both of the area for forming NMOS transistors and that for forming PMOS transistors, the performance enhancement occurs to both of NMOS and PMOS transistors. On the other hand, only PMOS transistors are sped up with the Ge-strained silicon technology in the prior art.

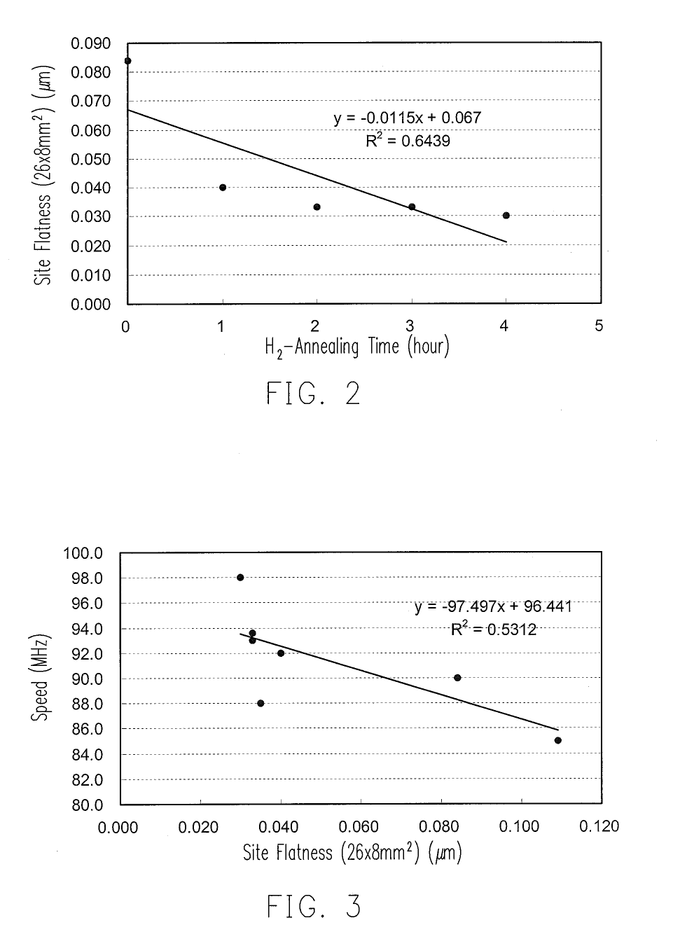

FIG. 2 plots the variation of the surface flatness of a silicon wafer with the H₂-annealing time in an example of this invention. In this example, the annealing was done in an H₂-atmosphere having a pressure slightly lower than 760 Torr after an STI structure was formed on the silicon wafer, at a temperature of about 1200° C. The site flatness was measured through a capacitive measurement using a wafer dimensional metrology system AFS-3240 manufactured by the ADE Corporation.

As shown in FIG. 2, the site flatness of the surface of the silicon wafer was reduced by about 50% after merely one hour of H₂-annealing, while further annealing did not much reduce the site flatness of the surface. Accordingly, the method of this invention can effectively reduce the site flatness of a surface of a semiconductor wafer.

FIG. 3 plots the variation of the speed of a 4T static dynamic random memory (SRAM) device with the site flatness of the wafer surface in the same example, wherein the linewidth of the SRAM process is 130 nm.

As shown in FIG. 3, as the site flatness is reduced from about 0.1 μm to about 0.04 μm, the speed is raised by about 10%. The sensitivity of the speed of the SRAM device to the site flatness is higher than 15%/0.1 μm when the site flatness is within the range of 0.03-0.12 μm. Since the roughness of the wafer surface was also reduced, respective contributions of the flatness reduction and the roughness reduction to the speed improvement are discussed later. It is noted that the correlation coefficient R² between the speed and the site flatness was 0.5312.

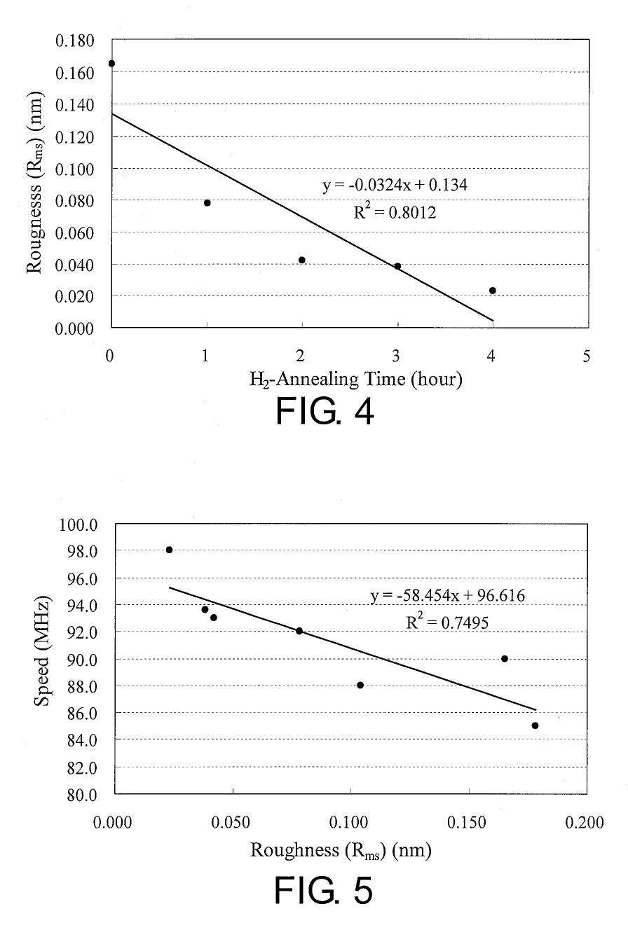

FIG. 4 plots the variation of the mean square roughness (Rₘₛ) of the silicon wafer with the H₂-annealing time in the same example of this invention. The mean square roughness is derived based on atomic force microscopy (AFM), using an atomic force microscope Nanoscope IIIa manufactured by Digital Instrument, USA.

As shown in FIG. 4, the Rₘₛ of the surface of the silicon wafer was reduced by about 50% to be smaller than 0.1 nm after merely one hour of H₂-annealing, and further annealing further reduced the Rₘₛ. Accordingly, the method of this invention reduces the roughness of the surface of a semiconductor wafer effectively. As the inventor knows, a roughness smaller than 0.1 nm is unique and can be made by H₂/D₂-annealing only.

FIG. 5 plots the variation of the speed of the 4T static dynamic random memory (SRAM) device with the Rₘₛ of the wafer surface in the same example, of this invention.

As shown in FIG. 5, as the Rₘₛ is reduced from about 0.1 nm to about 0.02 nm, the speed is raised by about 11%. The sensitivity of the speed of the SRAM device to the roughness is higher than 5%/Å when the roughness is within the range of 0.04-0.2 nm. It is also noted that the correlation coefficient R² between the speed and the Rₘₛ is 0.7495, which is relatively larger than that (0.5312) between the speed and the site flatness. Accordingly, roughness reduction contributes more to the speed improvement than site-flatness reduction does.

From FIGS. 2-5, it is confirmed that the H₂/D₂-annealing method of the invention can effectively reduce the site flatness and roughness of the surface of a semiconductor wafer and thereby effectively raise the speed of the semiconductor device to be formed on the wafer. Besides, in a comparative example that performs argon-annealing at the same temperature for the same time, the site flatness reduction is merely 5% that is within the range of the experimental error.

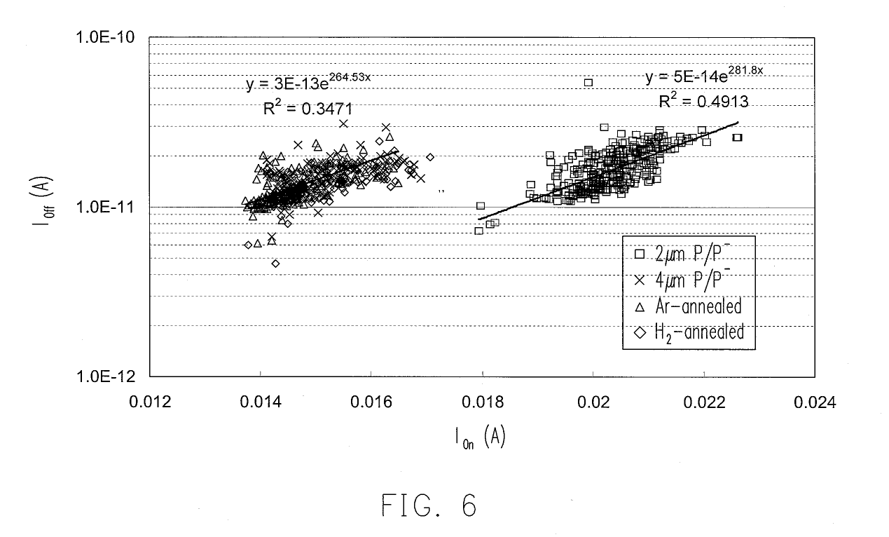

FIG. 6 shows the Iₒₙ-I_{off} correlations of four groups of 4T-SRAM devices in an experiment for studying the carrier mobility in the substrate, each group being formed on a Si-wafer that has been subjected to one of four different surface treatments including an H₂-annealing treatment of this invention. The linewidth of the SRAM process is 65 nm, and the Ar-annealing or H₂-annealing is conducted at about 1200° C. under a pressure slightly lower than 760 Torr for about 1 hour before the SRAM devices are formed. In addition, the 2 μm or 4 μm P/P⁻ treatment is to form a P/P⁻-doped epitaxial silicon layer having a thickness of 2 μm or 4 μm on the surface of a silicon wafer before the SRAM devices are formed.

As shown in FIG. 6, at the same level of I_{off}, the average Iₒₙ of the SRAM devices formed on the H₂-annealed wafer is larger by about 30% than that of the SRAM devices formed a wafer having been subjected to any of the other three treatments, which means that the carrier mobility can be improved effectively by H₂-annealing. It is thus confirmed that most of the speed improvement is contributed by the roughness reduction and the mobility improvement.

Furthermore, it is particularly noted that using D₂ only or using a mixed gas of H₂ and D₂ in the annealing has almost the same effects as using H₂ only, because the chemical properties of a D₂ molecule are almost the same as those of an H₂ molecule.

It will be apparent to those skilled in the art that various modifications and variations can be made to the structure of the present invention without departing from the scope or spirit of the invention. In view of the foregoing, it is intended that the present invention covers modifications and variations of this invention provided they fall within the scope of the following claims and their equivalents.

What is claimed is:

1. A method of increasing operation speed and saturated current of a semiconductor device to be formed on a semiconductor wafer, comprising:
a step of reducing a site flatness and a roughness of a surface of the semiconductor wafer before the semiconductor device is formed, the step comprising annealing the semiconductor wafer in an atmosphere that contains at least one of H₂ and D₂ and has a pressure not more than 760 Torr.

2. The method of claim 1, wherein the semiconductor wafer comprises at least one material selected from the group consisting of silicon, germanium and gallium arsenide (GaAs).

3. The method of claim 2, wherein the semiconductor wafer comprises silicon and is annealed at 1000-1400° C. for 1-4 hours.

4. The method of claim 2, wherein the semiconductor wafer comprises germanium or SiGe and is annealed at 800-1400° C. for 1-4 hours.

5. The method of claim 1, wherein the semiconductor wafer is doped with at least one dopant selected from the group consisting of boron, gallium, phosphorous and arsenic.

6. The method of claim 1, wherein the semiconductor wafer is a semiconductor-on-insulator (SOI) wafer.

7. The method of claim 1, which is performed before an isolation structure is formed on the semiconductor wafer.

8. The method of claim 1, which is performed after an isolation structure is formed on the semiconductor wafer.

9. The method of claim 1, wherein plasma is generated in the atmosphere.

10. The method of claim 9, wherein the semiconductor wafer is annealed at 400-800° C. for 1-4 hours.

11. The method of claim 1, wherein NMOS transistors and PMOS transistors are to be formed on the semiconductor wafer.

12. The method of claim 1, wherein the roughness is a mean square roughness and is reduced to be smaller than 0.1 nm.

13. The method of claim 1, wherein a sensitivity of a speed of the semiconductor device to the roughness is higher than 5%/Å when the roughness is within the range of 0.04-0.2 nm.

14. The method of claim 1, wherein a sensitivity of a speed of the semiconductor device to the site flatness is higher than 15%/0.1 μm when the site flatness is within the range of 0.03-0.12 μm.

15. A method of reducing a site flatness and a roughness of a surface of a semiconductor wafer, comprising annealing the semiconductor wafer in an atmosphere that contains at least one of H₂ and D₂ and has a pressure not more than 760 Torr.

16. The method of claim 15, wherein the semiconductor wafer comprises at least one material selected from the group consisting of silicon, germanium and GaAs.

17. The method of claim 16, wherein the semiconductor wafer comprises silicon and is annealed at 1000-1400° C. for 1-4 hours.

18. The method of claim 16, wherein the semiconductor wafer comprises SiGe or germanium and is annealed at 800-1400° C. for 1-4 hours.

19. The method of claim 15, wherein the semiconductor wafer is doped with at least one dopant selected from the group consisting of boron, gallium, phosphorous and arsenic.

20. The method of claim 15, wherein the semiconductor wafer is a semiconductor-on-insulator wafer.

21. The method of claim 15, which is performed before an isolation structure and a semiconductor device are formed on the semiconductor wafer.

22. The method of claim 15, which is performed after an isolation structure is formed on the semiconductor wafer but before a semiconductor device is formed on the semiconductor wafer.

23. The method of claim 15, wherein plasma is generated in the atmosphere.

24. The method of claim 23, wherein the semiconductor wafer is annealed at 400-800° C. for 1-4 hours.

25. The method of claim 15, wherein the semiconductor wafer includes areas for forming NMOS transistors and PMOS transistors respectively.

26. The method of claim 15, wherein the roughness is a mean square roughness and is reduced to be smaller than 0.1 nm.
